(19) United States
(12) Patent Application Publication
(10) Pub. No.: US 2026/0133481 A1
(43) Pub. Date: May 14, 2026

(54) SOURCE OPTIMIZATION FOR MITIGATING MASK ERROR IMPACT

(71) Applicant: ASML NETHERLANDS B.V., Veldhoven (NL)

(72) Inventors: Duan-Fu Stephen HSU, Fremont, CA (US); Jialei TANG, San Jose, CA (US); Youping ZHANG, Cupertino, CA (US)

(73) Assignee: ASML NETHERLANDS B.V., Veldhoven (NL)

(21) Appl. No.: 19/119,397

(22) PCT Filed: Oct. 6, 2023
(86) PCT No.: PCT/EP2023/077802

§ 371 Date: Apr. 8, 2025

Related U.S. Application Data
(60) Provisional application No. 63/420,853, filed on Oct. 31, 2022.

(51) Int. Cl. G03F 1/36; G01N 21/956; G03F 7/00

(52) U.S. Cl. CPC G03F 1/36; G01N 21/956; G03F 7/70441; G03F 7/705; G01N 2021/95676

(57) ABSTRACT

Systems, methods, and computer software are disclosed for reducing wafer patterning errors caused by a mask device. One method (300) can include obtaining a first mask design (310) having a first portion (324) associated with an optimized pupil (322), where the optimized pupil results from a source-mask optimization process (320). An error can be located on the mask device and a second portion (330) of the mask device with the error can be identified. The method can also include performing source optimization (340) by utilizing the first portion (324) and the second portion (330) in combination to generate a reoptimized pupil (350).

### CROSS-REFERENCE TO RELATED APPLICATIONS

This application claims priority of U.S. application 63/420,853 which was filed on Oct. 31, 2022 and which is incorporated herein in its entirety by reference.

### TECHNICAL FIELD

The description herein relates generally to mask manufacturing and patterning processes. More particularly, the disclosure includes apparatus, methods, and computer programs for optimizing a source to mitigate mask errors.

### BACKGROUND

A lithographic projection apparatus can be used, for example, in the manufacture of integrated circuits (ICs). In such a case, a “patterning device” or “mask device” (e.g., a mask) may contain or provide a pattern corresponding to an individual layer of the IC (“design layout”), and this pattern can be transferred onto a target portion (e.g., comprising one or more dies) on a substrate (e.g., silicon wafer) that has been coated with a layer of radiation-sensitive material (“resist”), by methods such as irradiating the target portion through the pattern on the mask device. In general, a single substrate contains a plurality of adjacent target portions to which the pattern is transferred successively by the lithographic projection apparatus, one target portion at a time. In one type of lithographic projection apparatuses, the pattern on the entire mask device is transferred onto one target portion in one go; such an apparatus may also be referred to as a stepper. In an alternative apparatus, a step-and-scan apparatus can cause a projection beam to scan over the mask device in a given reference direction (the “scanning” direction) while synchronously moving the substrate parallel or anti-parallel to this reference direction. Different portions of the pattern on the mask device are transferred to one target portion progressively. Since, in general, the lithographic projection apparatus will have a reduction ratio M (e.g., 4), the speed F at which the substrate is moved will be 1/M times that at which the projection beam scans the mask device. More information with regard to lithographic devices can be found in, for example U.S. Pat. No. 6,046,792, incorporated herein by reference.

Prior to transferring the pattern from the mask device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a mask device in a lithographic apparatus, to transfer a pattern on the mask device to a substrate and typically, but optionally, involves one or more related pattern processing steps, such as resist development by a development apparatus, baking of the substrate using a bake tool, etching using the pattern using an etch apparatus, etc.

As noted, lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the amount of functional elements, such as transistors, per device has been steadily increasing over decades, following a trend referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm. i.e. less than half the wavelength of the radiation from the illumination source (e.g., a 193 nm illumination source).

This process in which features with dimensions smaller than the classical resolution limit of a lithographic projection apparatus are printed, is can be referred to as low-k1 lithography, according to the resolution formula CD=k1×λ/NA, where λ is the wavelength of radiation employed (e.g., 248 nm or 193 nm). NA is the numerical aperture of projection optics in the lithographic projection apparatus. CD is the “critical dimension”—generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the mask device. These include, for example, but not limited to, optimization of NA and optical coherence settings, customized illumination schemes, use of phase shifting mask devices, optical proximity correction (OPC, sometimes also referred to as “optical and process correction”) in the design layout, or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the mask device, and/or optical components for shaping, adjusting and/or projecting the radiation after the radiation passes the mask device. The projection optics generally exclude the source and the mask device.

### SUMMARY

Systems, methods, and computer software are disclosed for reducing wafer patterning errors caused by a mask device. In one aspect, a method can include obtaining a first mask design having a first portion associated with an optimized pupil, where the optimized pupil results from a source-mask optimization process. An error can be located on the mask device and a second portion of the mask device with the error can be identified. The method can also include performing source optimization by utilizing the first portion and the second portion in combination to generate a reoptimized pupil.

In some variations, the method can include locating the error utilizing an inspection tool. This can include performing mask inspection of the mask device with the inspection tool or wafer inspection of a wafer with the inspection tool.

In other variations, the method can include obtaining a predicted result for the error. The second portion can be identified based on the predicted result. Also, the method can include determining that the predicted result for the error is above a local threshold.

In yet other variations, the method can include performing a lithographic manufacturing check (LMC) utilizing the mask device to obtain the predicted result for the second portion having the error. This can include determining with the LMC that the error is a process window limiter. The predicted result can be a mask error enhancement factor (MEEF) obtained by performing an LMC utilizing the mask device or a depth of focus (DOF) and the error reduces the DOF. Also, first portion may not have the error or may have a reduced error compared to the error in the second portion.

In some variations, the method can include identifying portions of the mask device having errors of a type of error, where the source optimization can be performed utilizing a portion where the error is the largest for the type of error. The type of error can be a bias (e.g., an X bias, a Y bias, an X and Y bias, etc.), an edge shift (e.g., an X edge shift, a Y edge shift, an X and Y edge shift, etc.), or an edge defect (e.g., an X edge defect, a Y edge defect, or an X and Y edge defect). The method can also include identifying portions of the mask device having different types of errors, where the source optimization is performed utilizing the portions that have the largest errors for the types of errors.

In other variations, the method can include applying weights to the first portion and the second portion, the weights selected to establish a relative contribution of the first portion and the second portion in generating the reoptimized pupil. The method can include obtaining a number of predicted results for the mask device, locating a plurality of first errors on the mask device based on the predicted results, and identifying a number of second portions of the mask device with the located plurality of errors, where the weights are assigned to the plurality of second portions that have a largest error of a type of error, with the number of second portions including the second portion. The weights can be iteratively adjusted during successive source optimizations to improve a process window. The mask device and the reoptimized pupil can result in the process window improved from the mask device and the optimized pupil.

In yet other variations, the source optimization can be performed for a lithography system utilizing a numerical aperture (NA) greater than or equal to 0.4 (e.g., 0.55). The method can include stitching a mask device layout for use with the lithography system having the NA where the mask device is projected with a magnification that maintains a mask reflectance above 0.5. The mask design can correspond to one of a DRAM layer, a Storage Node (SP) layer, a Storage Node Pad (SNP) layer, or array patterns. The method can include performing a vote-taking process utilizing the reoptimized pupil to generate a second reoptimized pupil or where generating the reoptimized pupil does not include performing a vote-taking process.

In some variations, the source optimization can include generating a discrete pupil, generating a free-form pupil, or generating a discrete pupil and a free-form pupil.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations. In the drawings.

FIG. 1 illustrates a block diagram of various subsystems of a lithographic projection apparatus, according to an embodiment of the present disclosure.

FIG. 2 illustrates an exemplary flow chart for simulating lithography in a lithographic projection apparatus, according to an embodiment of the present disclosure.

FIG. 3 is a process flow diagram illustrating performing source optimization to generate a reoptimized pupil that reduces the effect of mask error, according to an embodiment of the present disclosure.

FIG. 4 is a process flow diagram illustrating performing source optimization with weighted mask portions and process window analysis, according to an embodiment of the present disclosure.

FIG. 5 is a diagram illustrating a mask device having errors and depictions of different types of errors, according to embodiments of the present disclosure.

FIG. 6 is a diagram illustrating utilizing increased magnification for high-NA operation, according to embodiments of the present disclosure.

FIG. 7 is a diagram illustrating a stitching operation for use with some high-NA implementations, according to embodiments of the present disclosure.

FIG. 8 is a block diagram of an example computer system, according to an embodiment of the present disclosure.

FIG. 9 is a schematic diagram of a lithographic projection apparatus, according to an embodiment of the present disclosure.

FIG. 10 is a schematic diagram of another lithographic projection apparatus, according to an embodiment of the present disclosure.

FIG. 11 is a detailed view of the lithographic projection apparatus, according to an embodiment of the present disclosure.

FIG. 12 is a detailed view of the source collector module of the lithographic projection apparatus, according to an embodiment of the present disclosure.

### DETAILED DESCRIPTION

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”. “wafer” or “die” in this text should be considered as interchangeable with the more general terms “mask”. “substrate” and “target portion”, respectively.

In the present document, the terms “radiation” and “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 5-100 nm).

The mask device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/mask devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the mask device).

The term “mask” or “mask device” as employed in this text may be broadly interpreted as referring to a generic mask device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such mask devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic methods.

An example of a programmable LCD array is given in U.S. Pat. No. 5,229,872, which is incorporated herein by reference.

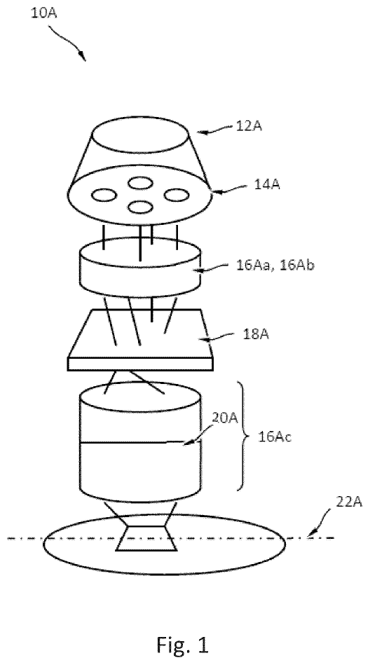

FIG. 1 illustrates a block diagram of various subsystems of a lithographic projection apparatus 10A, according to an embodiment of the present disclosure. Major components are a radiation source 12A, which may be a deep-ultraviolet excimer laser source or other type of source including an extreme ultraviolet (EUV) source (as discussed above, the lithographic projection apparatus itself need not have the radiation source), illumination optics which, e.g., define the partial coherence (denoted as sigma) and which may include optics 14A, 16Aa and 16Ab that shape radiation from the source 12A; a mask device 18A; and transmission optics 16Ac that project an image of the mask device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin (Θₘₐₓ), wherein n is the refractive index of the media between the substrate and the last element of the projection optics, and Θₘₐₓ is the largest angle of the beam exiting from the projection optics that can still impinge on the substrate plane 22A.

In a lithographic projection apparatus, a source provides illumination (i.e. radiation) to a mask device and projection optics direct and shape the illumination, via the mask device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. 2009-0157360, the disclosure of which is hereby incorporated by reference in its entirety. The resist model is related only to properties of the resist layer (e.g., effects of chemical processes which occur during exposure, post-exposure bake (PEB) and development). Optical properties of the lithographic projection apparatus (e.g., properties of the illumination, the mask device and the projection optics) dictate the aerial image and can be defined in an optical model. Since the mask device used in the lithographic projection apparatus can be changed, it is desirable to separate the optical properties of the mask device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosures of each are hereby incorporated by reference in their entirety.

One aspect of understanding a lithographic process is understanding the interaction of the radiation and the mask device. The electromagnetic field of the radiation after the radiation passes the mask device may be determined from the electromagnetic field of the radiation before the radiation reaches the mask device and a function that characterizes the interaction. This function may be referred to as the mask transmission function (which can be used to describe the interaction by a transmissive mask device and/or a reflective mask device).

The mask transmission function may have a variety of different forms. One form is binary. A binary mask transmission function has either of two values (e.g., zero and a positive constant) at any given location on the mask device. A mask transmission function in the binary form may be referred to as a binary mask. Another form is continuous. Namely, the modulus of the transmittance (or reflectance) of the mask device is a continuous function of the location on the mask device. The phase of the transmittance (or reflectance) may also be a continuous function of the location on the mask device. A mask transmission function in the continuous form may be referred to as a continuous tone mask or a continuous transmission mask (CTM). For example, the CTM may be represented as a pixelated image, where each pixel may be assigned a value between 0 and 1 (e.g., 0.1, 0.2, 0.3, etc.) instead of binary value of either (or 1. In an embodiment. CTM may be a pixelated gray scale image, where each pixel having values (e.g., within a range [−255, 255], normalized values within a range [0, 1] or [−1, 1] or other appropriate ranges).

The thin-mask approximation, also called the Kirchhoff boundary condition, is widely used to simplify the determination of the interaction of the radiation and the mask device. The thin-mask approximation assumes that the thickness of the structures on the mask device is very small compared with the wavelength and that the widths of the structures on the mask are very large compared with the wavelength. Therefore, the thin-mask approximation assumes the electromagnetic field after the mask device is the multiplication of the incident electromagnetic field with the mask transmission function. However, as lithographic processes use radiation of shorter and shorter wavelengths, and the structures on the mask device become smaller and smaller, the assumption of the thin-mask approximation can break down. For example, interaction of the radiation with the structures (e.g., edges between the top surface and a sidewall) because of their finite thicknesses (“mask 3D effect” or “M3D”) may become significant. Encompassing this scattering in the mask transmission function may enable the mask transmission function to better capture the interaction of the radiation with the mask device. A mask transmission function under the thin-mask approximation may be referred to as a thin-mask transmission function. A mask transmission function encompassing M3D may be referred to as a M3D mask transmission function.

According to an embodiment of the present disclosure, one or more images may be generated. The images includes various types of signal that may be characterized by pixel values or intensity values of each pixel. Depending on the relative values of the pixel within the image, the signal may be referred as, for example, a weak signal or a strong signal, as may be understood by a person of ordinary skill in the art. The term “strong” and “weak” are relative terms based on intensity values of pixels within an image and specific values of intensity may not limit scope of the present disclosure. In an embodiment, the strong and weak signal may be identified based on a selected threshold value. In an embodiment, the threshold value may be fixed (e.g., a midpoint of a highest intensity and a lowest intensity of pixel within the image. In an embodiment, a strong signal may refer to a signal with values greater than or equal to an average signal value across the image and a weak signal may refer to signal with values less than the average signal value. In an embodiment, the relative intensity value may be based on percentage. For example, the weak signal may be signal having intensity less than 50% of the highest intensity of the pixel (e.g., pixels corresponding to target pattern may be considered pixels with highest intensity) within the image. Furthermore, each pixel within an image may considered as a variable. According to the present embodiment, derivatives or partial derivative may be determined with respect to each pixel within the image and the values of each pixel may be determined or modified according to a cost function based evaluation and/or gradient based computation of the cost function. For example, a CTM image may include pixels, where each pixel is a variable that can take any real value.

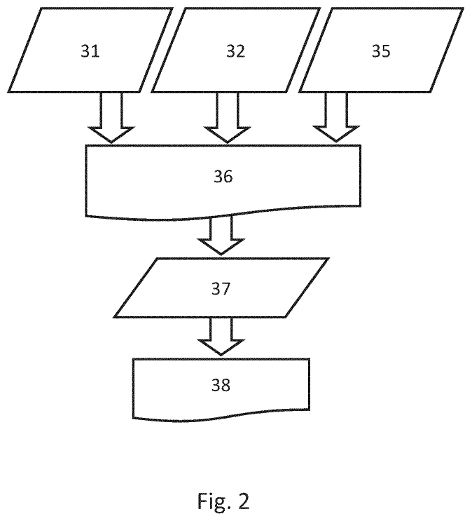

FIG. 2 illustrates an exemplary flow chart for simulating lithography in a lithographic projection apparatus, according to an embodiment of the present disclosure. Source model 31 represents optical characteristics (including radiation intensity distribution and/or phase distribution) of the source. Projection optics model 32 represents optical characteristics (including changes to the radiation intensity distribution and/or the phase distribution caused by the projection optics) of the projection optics. Design layout model 35 represents optical characteristics of a design layout (including changes to the radiation intensity distribution and/or the phase distribution caused by design layout 33), which is the representation of an arrangement of features on or formed by a mask device. Aerial image 36 can be simulated from design layout model 35, projection optics model 32, and design layout model 35. Resist image 38 can be simulated from aerial image 36 using resist model 37. Simulation of lithography can, for example, predict contours and CDs in the resist image.

More specifically, it is noted that source model 31 can represent the optical characteristics of the source that include, but not limited to, numerical aperture settings, illumination sigma (σ) settings as well as any particular illumination shape (e.g., off-axis radiation sources such as annular, quadrupole, dipole, etc.). Projection optics model 32 can represent the optical characteristics of the projection optics, including aberration, distortion, one or more refractive indexes, one or more physical sizes, one or more physical dimensions, etc. Design layout model 35 can represent one or more physical properties of a physical mask device, as described, for example, in U.S. Pat. No. 7,587,704, which is incorporated by reference in its entirety. The objective of the simulation is to accurately predict, for example, edge placement, aerial image intensity slope and/or CD, which can then be compared against an intended design. The intended design is generally defined as a pre-OPC design layout which can be provided in a standardized digital file format such as GDSII or OASIS or other file format.

From this design layout, one or more portions may be identified, which are referred to as “clips”. In an embodiment, a set of clips is extracted, which represents the complicated patterns in the design layout (typically about 50 to 1000 clips, although any number of clips may be used). These patterns or clips represent small portions (i.e. circuits, cells or patterns) of the design and more specifically, the clips typically represent small portions for which particular attention and/or verification is needed. In other words, clips may be the portions of the design layout, or may be similar or have a similar behavior of portions of the design layout, where one or more critical features are identified either by experience (including clips provided by a customer), by trial and error, or by running a full-chip simulation. Clips may contain one or more test patterns or gauge patterns.

An initial larger set of clips may be provided a priori by a customer based on one or more known critical feature areas in a design layout which require particular image optimization. Alternatively, in another embodiment, an initial larger set of clips may be extracted from the entire design layout by using some kind of automated (such as machine vision) or manual algorithm that identifies the one or more critical feature areas.

In a lithographic projection apparatus, as an example, a cost function may be expressed as

$$C F ( {z}_{1} , {z}_{2} , … , {z}_{N} ) = {\sum }_{p = 1}^{P} {w}_{ρ} {f}_{p}^{2} ( {z}_{1} , {z}_{2} , … , {z}_{N} ) \qquad ( Eq . 1 )$$

where (z₁, z₂, . . . , z_{N}) are N design variables or values thereof, fₚ(z₁, z₂, . . . , z_{N}) can be a function of the design variables (z₁, z₂, . . . , z_{N}) such as a difference between an actual value and an intended value of a characteristic for a set of values of the design variables of (z₁, z₂, . . . , z_{N}). wₚ is a weight constant associated with fₚ(z₁, z₂, . . . , z_{N}). For example, the characteristic may be a position of an edge of a pattern, measured at a given point on the edge. Different fₚ(z₁, z₂, . . . , z_{N}) may have different weight wₚ. For example, if a particular edge has a narrow range of permitted positions, the weight wₚ for the fₚ(z₁, z₂, . . . , z_{N}) representing the difference between the actual position and the intended position of the edge may be given a higher value, fₚ(z₁, z₂, . . . , z_{N}) can also be a function of an interlayer characteristic, which is in turn a function of the design variables (z₁, z₂, . . . , z_{N}). Of course. CF(z₁, z₂, . . . , z_{N}) is not limited to the form in Eq. 1. CF(z₁, z₂, . . . , z_{N}) can be in any other suitable form.

The cost function may represent any one or more suitable characteristics of the lithographic projection apparatus, lithographic process or the substrate, for instance, focus. CD, image shift, image distortion, image rotation, stochastic variation, throughput, local CD variation, process window, an interlayer characteristic, or a combination thereof. In one embodiment, the design variables (z₁, z₂, . . . , z_{N}) comprise one or more selected from dose, global bias of the mask device, and/or shape of illumination. Since it is the resist image that often dictates the pattern on a substrate, the cost function may include a function that represents one or more characteristics of the resist image. For example, fₚ(z₁, z₂, . . . , z_{N}) can be simply a distance between a point in the resist image to an intended position of that point (i.e., edge placement error EPEₚ(z₁, z₂, . . . , z_{N}). The design variables can include any adjustable parameter such as an adjustable parameter of the source, the mask device, the projection optics, dose, focus, etc.

The lithographic apparatus may include components collectively called a “wavefront manipulator” that can be used to adjust the shape of a wavefront and intensity distribution and/or phase shift of a radiation beam. In an embodiment, the lithographic apparatus can adjust a wavefront and intensity distribution at any location along an optical path of the lithographic projection apparatus, such as before the mask device, near a pupil plane, near an image plane, and/or near a focal plane. The wavefront manipulator can be used to correct or compensate for certain distortions of the wavefront and intensity distribution and/or phase shift caused by, for example, the source, the mask device, temperature variation in the lithographic projection apparatus, thermal expansion of components of the lithographic projection apparatus, etc. Adjusting the wavefront and intensity distribution and/or phase shift can change values of the characteristics represented by the cost function. Such changes can be simulated from a model or actually measured. The design variables can include parameters of the wavefront manipulator.

The design variables may have constraints, which can be expressed as (z₁, z₂, . . . , z_{N})∈Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. For example, if the dose is a design variable, without such a constraint, the optimization may yield a dose value that makes the throughput economically impossible. However, the usefulness of constraints should not be interpreted as a necessity. For example, the throughput may be affected by the pupil fill ratio. For some illumination designs, a low pupil fill ratio may discard radiation, leading to lower throughput. Throughput may also be affected by the resist chemistry. Slower resist (e.g., a resist that requires higher amount of radiation to be properly exposed) leads to lower throughput.

As used herein, the term “patterning process” means a process that creates an etched substrate by the application of specified patterns of light as part of a lithography process.

As used herein, the term “target pattern” means an idealized pattern that is to be etched on a substrate.

As used herein, the term “printed pattern” means the physical pattern on a substrate that was formed based on a design layout. The printed pattern can include, for example, vias, contact holes, troughs, channels, depressions, edges, or other two and three dimensional features resulting from a lithography process.

As used herein, the term “process model” means a model that includes one or more models that simulate a patterning process. For example, a process model can include any combination of: an optical model (e.g., that models a lens system/projection system used to deliver light in a lithography process and may include modelling the final optical image of light that goes onto a photoresist), a mask model, a resist model (e.g., that models physical effects of the resist, such as chemical effects 30) due to the light), an OPC model (e.g., that can be used to make design layouts and may include sub-resolution resist features (SRAFs), etc.), an inspection tool model (e.g., that models what an inspection tool may image from a printed pattern).

As used herein, the term “inspection tool” means any number or combination of devices and associated computer hardware and software that can be configured to generate images of a target, such as the printed pattern or portions thereof. Non-limiting examples of inspection tools can include: scanning electron microscopes (SEMs), x-ray machines, etc.

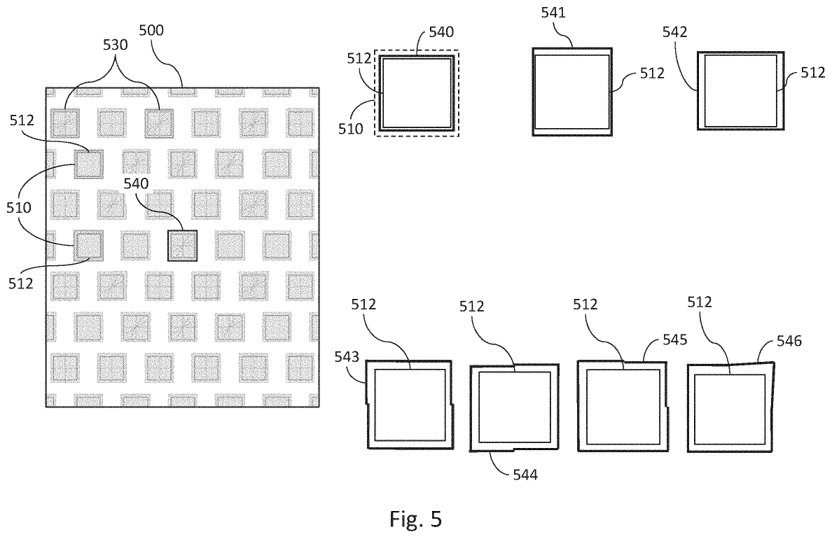

Manufactured mask devices (e.g., masks) sometimes have errors such as shifts in the locations or altered sizes of certain features in the mask (e.g., see FIG. 5 for some examples of errors). Mitigating the effect of wafer errors caused by such a mask device can be performed by “vote taking.” which is a processing procedure where the incident light and/or mask device is physically shifted to several (N) locations that have the same design features as one with an error, with a reduced exposure (1/N) performed at each location. While such a vote-taking approach can be performed in accordance with certain embodiments of the present disclosure, the number of exposures performed during vote taking can reduce manufacturing throughput and so can be avoided or reduced by utilizing the disclosed processes.

According to embodiment of the present disclosure, printing effects of mask device errors can be mitigated by performing source optimization with the identified error features on the defective mask device to generate a reoptimized pupil. This has the advantage of improving the manufacturing process without having to manufacture a new mask device. The reoptimized source (e.g., pupil) can advantageously eliminate or reduce the need for time-consuming vote taking. These improvements can be quantified by, for example, calculating the process window (or other metrics), which can then enable iterative optimization of the source to obtain a pupil providing the most process window improvement. Such methods can also be implemented with high-NA (e.g., NA>0.4) operations where the mask device is utilized with a stitching operation that may itself cause a decrease in throughput and so benefits by avoiding vote-taking procedures.

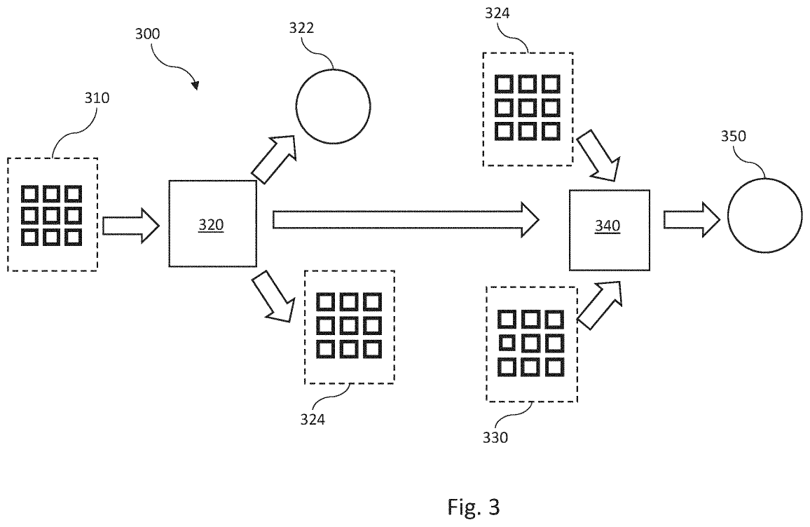

FIG. 3 is a process flow diagram illustrating performing source optimization to generate a reoptimized pupil that reduces the effect of mask error, according to an embodiment of the present disclosure. To provide an overview of some aspects of the present disclosure, one process 300 for reducing the effect of mask errors can includes specifying a design target 310 for a source-mask optimization process 320. Performing the source-mask optimization process 320 can produce an optimized pupil 322 and a first mask design having a first portion 324 having no (or reduced) errors. In some embodiments, the mask design can correspond to a DRAM layer, a Storage Node (SP) layer, a Storage Node Pad (SNP) layer, or array patterns. To reduce the effect of an error in an already produced mask device, first portion 324 (from an SMO process or alternatively from measured mask data from a mask without the error) and second portion 330 (from the mask device) can be utilized in a source optimization 340 to produce a reoptimized pupil 350. The second portion 330 can be representative mask data, for example, an OPC mask pattern for the mask device. Because the source optimization 340 attempts to account for the physical errors in the mask device and also account for an “ideal” mask design that in principle results in an optimal production of design target 310 at the wafer, the resulting reoptimized pupil, when used with the mask device, produces wafers where the effect of the error(s) present in the mask device are reduced.

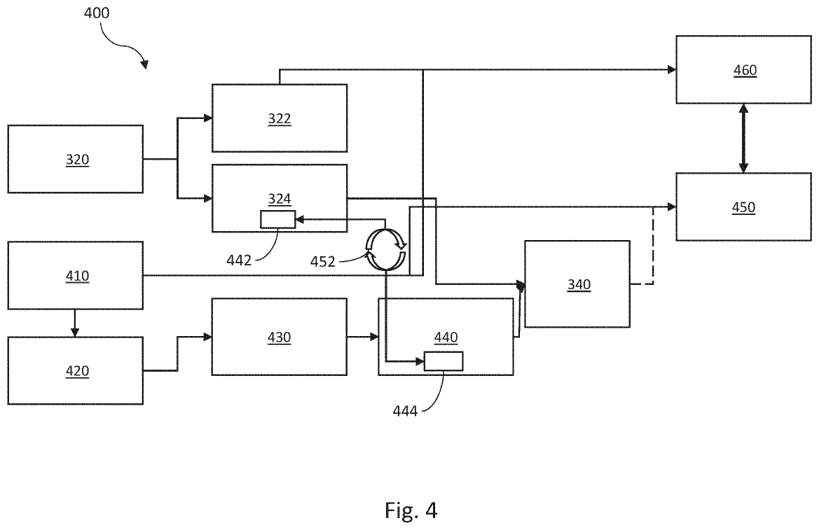

FIG. 4 is a process flow diagram illustrating performing source optimization with weighted mask portions and process window analysis, according to an embodiment of the present disclosure. The process 400 depicted in FIG. 4 includes features from the process 300 in FIG. 3 but with additional details that can be included, in any combination. As depicted in FIG. 4, process 400 can reduce wafer patterning errors caused by a mask device. For example, as described in further detail below, this can include weighting the contributions of first portion 324 and second portion 330 such that the reoptimized pupil 350 can be based on contributions from both, thereby reducing the effects of the error(s) present in second portion 330 while still accounting somewhat for the physical mask being utilized.

In one embodiment, process 400 can include obtaining a first mask design (including first portion 324) associated with an optimized pupil 322, where the optimized pupil 322 and first mask design can result from source-mask optimization process 320. In some embodiments, following source-mask optimization 320, optical proximity correction can be performed to produce a mask design. The mask design can then be manufactured. With the mask design or measurements from the manufactured mask, first portion 324 can be obtained and used as described herein.

At 410, process 400 can include locating an error on the mask device. Examples of errors are provided with reference to FIG. 5. Locating errors on the mask device can include, for example, performing mask inspection of the mask device with the inspection tool, performing wafer inspection of a wafer with the inspection tool, etc. In general, a mask device may contain many errors and many types of errors. Any number and types of such errors can therefore be located by performing the mask and/or wafer inspection.

At 420, a predicted result that represents the effect of errors can be obtained for the mask device (or wafer). The predicted result can include, for example, a mask error enhancement factor (MEEF) obtained by performing an LMC utilizing the mask device, a depth of focus (DOF) with the error reducing the DOF, etc. The predicted result can be calculated for any of the errors found on the mask device during the mask or wafer inspection. In some embodiments, this can include determining that the predicted result for the error is above a local threshold. Inspection tools can be utilized to locate the error. In some embodiments, this can include performing a lithographic manufacturing check (LMC) utilizing the mask device to obtain the predicted result for the second portion having the error. Also, utilizing the LMC can determine that the error is a process window limiter. For example, this can be where the error limits the process window as opposed to other errors that may not directly affect the PW even if above the threshold amount—e.g., such as having a large X shift in a location where X shifts do not impact the PW. In other embodiments, the error can be a hotspot, a location with a large edge placement error (EPE), critical dimension (CD) errors, etc.

At 430, process 400 can include determining representative error locations (e.g., a particular subset of the errors that may be present). The present disclosure is not limited to a specific number of representative error locations, specific types of errors or specific methods of selecting representative error locations. For example, this can include identifying a portion (e.g., second portion 330) of the mask device with the error, the identifying based on the predicted result (e.g., identifying portion(s) with errors causing a high MEEF). For example, the portion can correspond to a mask clip, such as can be utilized for SMO. Representative defect locations can include those mask locations with errors of different types, and/or errors above a certain threshold. For example, second portion 330 could be a portion having an X bias. Other similar portions of the mask device can include portions having a Y bias, an edge shift, etc. By representing different types of errors, process 400 can generate a reoptimized pupil that can reduce the effects of multiple types of errors.

In some embodiments, at 440, process 400 can include identifying portions (e.g., including second portion 330) of the mask device having errors that each have a type of error (e.g., biases, edge shifts, etc.). Examples of types of errors are further described with reference to FIG. 5. In one embodiment, a mask device may have portions with only one type of error (e.g., a bias in X). In such embodiments, the source optimization can be performed utilizing a portion where the error is the largest for the type of error. For example, if the portions have different biases in X, this can include utilizing a portion with a largest bias in X. Other embodiments can include identifying portions of the mask device having different types of errors (e.g., X bias, Y bias, etc.). In some embodiments the source optimization can be performed utilizing the portions that have the largest errors for particular types of errors. For example, this can include utilizing portions with a largest bias in X, largest bias in Y, etc.

As the first portion (from an SMO) and the second portion (with the error(s)) can be utilized as inputs to the source optimization, weights can be applied to the first portion 324 and the second portion 330. The weights can be selected to establish a relative contribution of the first portion 324 and the second portion 330 in generating the reoptimized pupil. For example, the first portion can have a first weight 442 of 3, 4, 5, etc. and the second portion can have a second weight 444 of 1, 2, etc.

Similar to the identification of portions performed at 440, process 400 can weight multiple portions respectively. For example, in some embodiments, process 400 can include obtaining predicted results for the mask device and locating first errors on the mask device based on the predicted results. Process 400 can then include identifying second portions of the mask device with the located errors, where the weights can be assigned to the second portions that have the largest error of a type of error. For example, there can be second portions with X biases and Y biases, and the particular second portions used can be the two second portions with the largest X bias and the largest Y bias, with each second portion having a respective weight.

Process 400 can include performing source optimization 340 by utilizing the first portion 324 and a second portion 330 of the mask device to generate reoptimized pupil 350. In some embodiments, first portion 324 may not have the error or may have a reduced error compared to the error in the second portion 330. Again, the source optimization can thus act to generate the reoptimized pupil that can result in an improved mask due to accounting for the more ideal first mask design. Accordingly, various embodiments of the present disclosure can allow generating the reoptimized pupil 350 without including performing a vote-taking process, which can be time consuming (e.g., by increasing total exposure time by a factor of N as described above), and as such can greatly decrease throughput. However, other embodiments can include performing a vote-taking process utilizing the reoptimized pupil 350 to generate a second reoptimized pupil. This can be performed, for example, for comparing improvements in throughput, process windows, etc.

In some embodiments, the source optimization can include generating a free-form pupil (e.g., a pupil where values at given locations have a range of intensities). In other embodiments, the source optimization can generate a discrete pupil (e.g., a pupil where the output is discrete at various locations). In yet other embodiments, the source optimization can include generating a discrete pupil and a free-form pupil, for example where a discrete pupil is generated by the source optimization and then converted to a discrete pupil to be used for process window analysis.

The present disclosure is not limited to any specific algorithms, methods, or process used for source re-optimization. At 450, process window analysis can be performed to characterize the error reduction of the reoptimized pupil. In some embodiments, this can include iteratively adjusting the weights during successive source optimizations to improve the process window. This is represented in FIG. 4 by the iteration loop 452 where first weight 442 and second weight 444 can be adjusted. In embodiments where first portion 324 and/or second portion 330 include more than one portion (or clip) of their respective masks, each portion/clip can have its own individual weight. To determine whether the process window is improving. PW analysis 450 can be performed based on the mask device and the reoptimized pupil obtained from the source optimization 340 and compared to PW analysis 460 performed based on the optimized pupil 322 and the first mask design obtained from the source-mask optimization process 320. As such, in some embodiments, the iteration loop 452 can continue until the mask device combined with the reoptimized pupil result in the process window improved from the mask device and the optimized pupil. In other embodiments, the iteration can continue until the improvement is a maximum or until a certain number of iterations have been performed.

FIG. 5 is a diagram illustrating a mask device having errors and depictions of different types of errors, according to embodiments of the present disclosure. One example of a mask device 500 is shown having a number of mask features 510 intended to generate target patterns 512 on a wafer. In some embodiments, the mask features 510 can be slightly oversized, but of particular dimensions, to generate the target patterns. However, mask device 500 also is depicted as having a number of errors 530 (shown in mask device 500 as portions with diagonal lines within), with a critical error 540 in this example shown near the middle of mask device 500. As described herein, some embodiments can include identifying a first portion of mask device 500 such that it includes the critical error 540.

Also shown in FIG. 5 are different types of errors. For example, the type of error can be a bias (e.g., an X and Y bias, as shown for critical error 540. X bias 541. Y bias 542, etc.) where the dimension is too large or too small. The critical error 540 having X and Y bias is shown in an expanded view and is an example of both an X and Y bias where the X and Y dimensions are both undersized by an amount below a particular threshold. Also shown is a dashed line representing what the mask feature 510 would look like without critical error 540. Other types of errors can include an edge shift (e.g., X edge shift 543. Y edge shift 544. X and Y edge shift 545, etc.). Yet other types of errors can include edge defects (e.g., X edge defect. Y edge defect. X and Y edge defect 546).

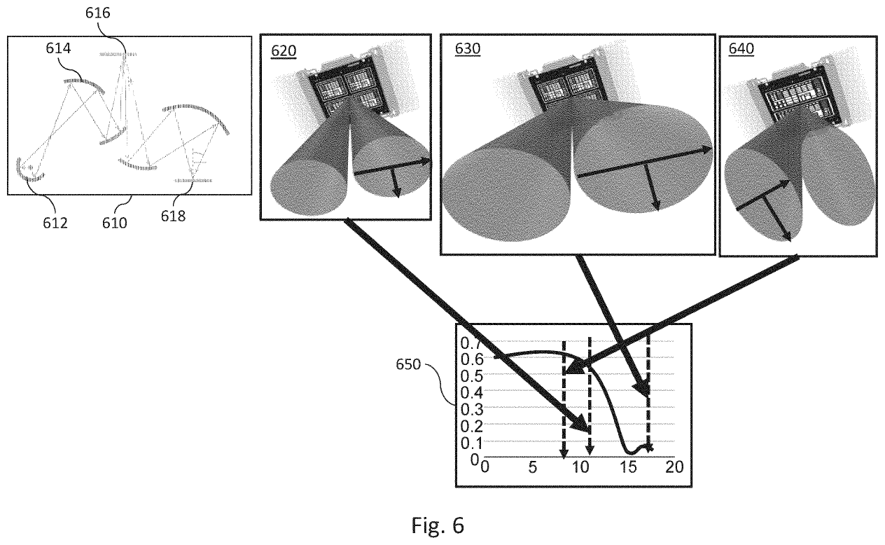

FIG. 6 is a diagram illustrating utilizing increased magnification for high-NA operation, according to embodiments of the present disclosure. The present disclosure can be applied to general pupils for deep ultraviolet (DUV) systems, extreme ultraviolet (EUV) system, any kind of masks, systems with any numerical aperture (NA), applications utilizing stitching and/or non-stitching. However, some embodiments of the present disclosure can include the source optimization performed for a lithography system utilizing a numerical aperture greater than or equal to 0.4 (e.g., 0.5, 0.55, 0.6, etc.), herein generally referred to as “high-NA.” Inset 610 depicts an exemplary lithography system having source 612, illumination optics 614, mask device 616, and wafer 618. Inset 620 shows a simplified depiction of a “typical” NA configuration (0.33 NA) in a lithography apparatus. The cones represent the optical angles (e.g., ˜4.7×11.3 degrees) of source light that can be delivered during wafer manufacture, particularly with anamorphic lenses that provide different stretching or compression of delivered light along different axes, as shown. Inset 630 depicts an example of a high-NA configuration, showing correspondingly larger optical angles (e.g., ˜8 and 18 degrees) and can therefore provide substantially resolution. However, the larger angles this can also result in a significant decrease in mask reflectance such that the amount of light reaching the wafer is substantially reduced. Some embodiments can mitigate this effect by operating at a higher magnification as shown in inset 640, where one axis of the optical cones is shown to be smaller even than for the 0.33 NA configuration. As a result, the reflectance can not only be recovered but can be optimized to be increased, e.g., to be at or near a maximum. This is depicted in plot 650, showing the change in reflectance going from 0.33 NA (11 degrees at 4× magnification), to 0.55 NA (18 degrees at 4× magnification), to 0.55 NA (9 degrees at 8× magnification).

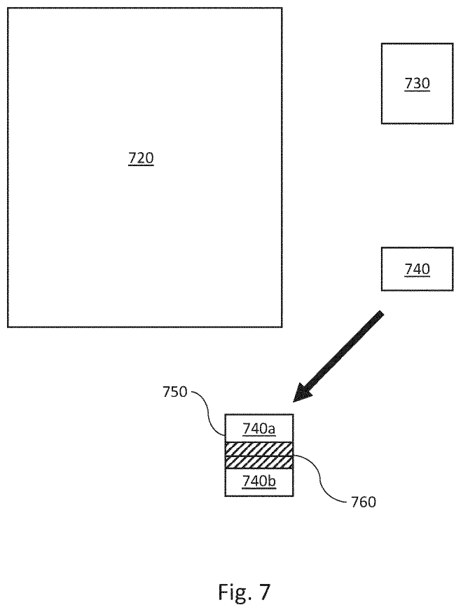

FIG. 7 is a diagram illustrating a stitching operation for use with some high-NA implementations, according to embodiments of the present disclosure. In some embodiments, the disclosed methods can include stitching a mask device layout for use with the lithography system having the NA where the mask device is projected with a magnification that maintains a mask reflectance above 0.5. Stitching can be utilized when the magnification reduces the available area for delivery of light. For example, area 720 can be produced as shown by inset 620 in FIG. 6 depicting a 4× magnification at 0.33 NA. Area 730 can be produced as shown by inset 630 in FIG. 6 depicting a 4× magnification at 0.55 NA but with an area 4× smaller due to the higher NA. By increasing the magnification further (e.g., 8×) the reflectance can be recovered but area 740 is now 8× smaller. Inset 750 depicts a stitching operation utilized to stitch two high NA areas 740a and 740b. Each area 740a and 740b covers the size of area 740 but each also include a stitching region 760 that overlaps when areas 740a and 740b are stitched. Area 740a and 740b together can print the same size area utilized for the desired high-NA operations (e.g., area 730). However, by generating the reoptimized pupil according to the methods described herein, stitching can be performed with only a double exposure in the stitching region 760, rather than 4× or more exposures as would be required with some vote-taking procedures.

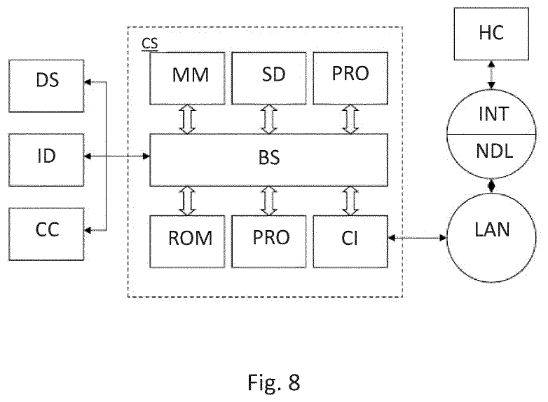

FIG. 8 is a block diagram of an example computer system CS, according to an embodiment of the present disclosure.

Computer system CS includes a bus BS or other communication mechanism for communicating information, and a processor PRO (or multiple processor) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions to be executed by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

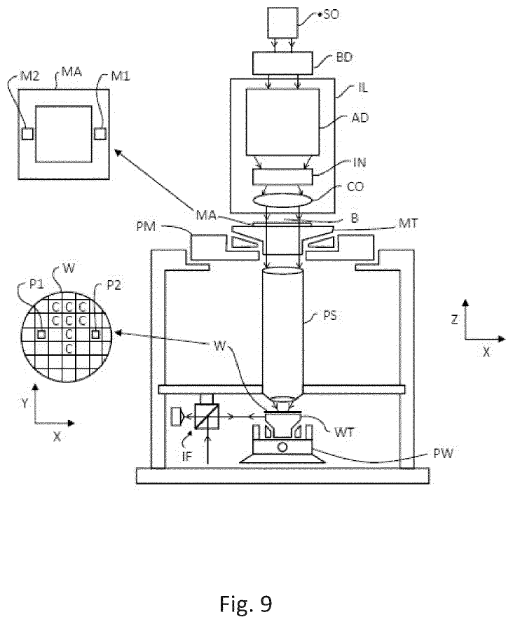

FIG. 9 is a schematic diagram of a lithographic projection apparatus, according to an embodiment of the present disclosure.

The lithographic projection apparatus can include an illumination system IL, a first object table MT, a second object table WT, and a projection system PS.

Illumination system IL, can condition a beam B of radiation. In this particular case, the illumination system also comprises a radiation source SO.

First object table (e.g., mask device table) MT can be provided with a mask device holder to hold a mask device MA (e.g., a reticle), and connected to a first positioner to accurately position the mask device with respect to item PS.

Second object table (substrate table) WT can be provided with a substrate holder to hold a substrate W (e.g., a resist-coated silicon wafer), and connected to a second positioner to accurately position the substrate with respect to item PS.

Projection system (“lens”) PS (e.g., a refractive, catoptric or catadioptric optical system) can image an irradiated portion of the mask device MA onto a target portion C (e.g., comprising one or more dies) of the substrate W.

As depicted herein, the apparatus can be of a transmissive type (i.e., has a transmissive mask device). However, in general, it may also be of a reflective type, for example (with a reflective mask device). The apparatus may employ a different kind of mask device than a classic mask; examples include a programmable mirror array or LCD matrix.

The source SO (e.g., a mercury lamp or excimer laser. LPP (laser produced plasma) EUV source) produces a beam of radiation. This beam is fed into an illumination system (illuminator) IL, either directly or after having traversed conditioning apparatuses, such as a beam expander Ex, for example. The illuminator IL may comprise adjusting device AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the mask device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus, the radiation beam that it produces being led into the apparatus (e.g., with the aid of suitable directing mirrors); this latter scenario can be the case when source SO is an excimer laser (e.g., based on KrF, ArF or F2 lasing).

The beam PB can subsequently intercept mask device MA, which is held on a mask device table MT. Having traversed mask device MA, the beam B can pass through the lens PL, which focuses beam B onto target portion C of substrate W. With the aid of the second positioning apparatus (and interferometric measuring apparatus IF), the substrate table WT can be moved accurately, e.g., so as to position different target portions C in the path of beam PB. Similarly, the first positioning apparatus can be used to accurately position mask device MA with respect to the path of beam B, e.g., after mechanical retrieval of the mask device MA from a mask device library, or during a scan. In general, movement of the object tables MT. WT can be realized with the aid of a long-stroke module (coarse positioning) and a short-stroke module (fine positioning). However, in the case of a stepper (as opposed to a step-and-scan tool) mask device table MT may just be connected to a short stroke actuator, or may be fixed.

The depicted tool can be used in two different modes, step mode and scan mode. In step mode, mask device table MT is kept essentially stationary, and an entire mask device image is projected in one go (i.e., a single “flash”) onto a target portion C. Substrate table WT can be shifted in the x and/or y directions so that a different target portion C can be irradiated by beam PB.

In scan mode, essentially the same scenario applies, except that a given target portion C is not exposed in a single “flash.” Instead, mask device table MT is movable in a given direction (the so-called “scan direction”, e.g., the y direction) with a speed v, so that projection beam B is caused to scan over a mask device image; concurrently, substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

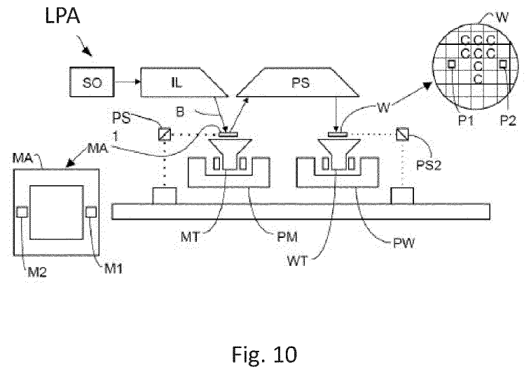

FIG. 10 is a schematic diagram of another lithographic projection apparatus (LPA), according to an embodiment of the present disclosure.

LPA can include source collector module SO, illumination system (illuminator) IL configured to condition a radiation beam B (e.g., EUV radiation), support structure MT, substrate table WT, and projection system PS.

Support structure (e.g., a mask device table) MT can be constructed to support a mask device (e.g., a mask or a reticle) MA and connected to a first positioner PM configured to accurately position the mask device;

Substrate table (e.g., a wafer table) WT can be constructed to hold a substrate (e.g., a resist coated wafer) W and connected to a second positioner PW configured to accurately position the substrate.

Projection system (e.g., a reflective projection system) PS can be configured to project a pattern imparted to the radiation beam B by mask device MA onto a target portion C (e.g., comprising one or more dies) of the substrate W.

As here depicted. LPA can be of a reflective type (e.g., employing a reflective mask device). It is to be noted that because most materials are absorptive within the EUV wavelength range, the mask device may have multilayer reflectors comprising, for example, a multi-stack of moly bdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the mask device topography (e.g., a TaN absorber on top of the multi-layer reflector) defines where features would print (positive resist) or not print (negative resist).

Illuminator IL can receive an extreme ultraviolet radiation beam from source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. Source collector module SO may be part of an EUV radiation system including a laser for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser may not be considered to form part of the lithographic apparatus and the radiation beam can be passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

Illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the mask device (e.g., mask) MA, which is held on the support structure (e.g., mask device table) MT, and is patterned by the mask device. After being reflected from the mask device (e.g., mask) MA, the radiation beam B passes through the projection system PS, which focuses the beam onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of radiation beam B. Similarly, the first positioner PM and another position sensor PS1 can be used to accurately position the mask device (e.g., mask) MA with respect to the path of the radiation beam B. Mask device (e.g., mask) MA and substrate W may be aligned using mask device alignment marks M1, M2 and substrate alignment marks P1, P2.

The depicted apparatus LPA could be used in at least one of the following modes, step mode, scan mode, and stationary mode.

In step mode, the support structure (e.g., mask device table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

In scan mode, the support structure (e.g., mask device table) MT and the substrate table WT are scanned synchronously while a pattern imparted to the radiation beam is projected onto target portion C (i.e. a single dynamic exposure). The velocity and direction of substrate table WT relative to the support structure (e.g., mask device table) MT may be determined by the (de-)magnification and image reversal characteristics of the projection system PS.

In stationary mode, the support structure (e.g., mask device table) MT is kept essentially stationary holding a programmable mask device, and substrate table WT is moved or scanned while a pattern imparted to the radiation beam is projected onto a target portion C. In this mode, generally a pulsed radiation source is employed and the programmable mask device is updated as required after each movement of the substrate table WT or in between successive radiation pulses during a scan. This mode of operation can be readily applied to maskless lithography that utilizes programmable mask devices, such as a programmable mirror array.

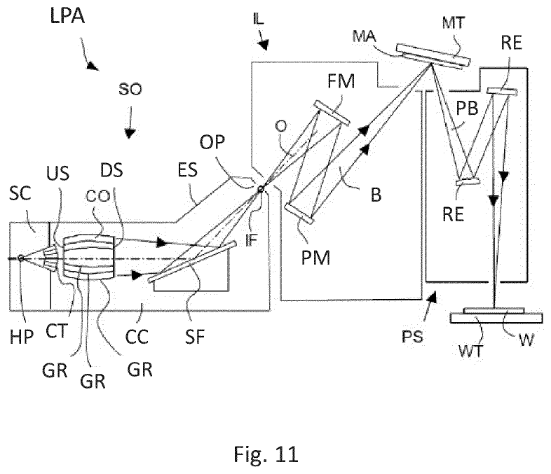

FIG. 11 is a detailed view of the lithographic projection apparatus, according to an embodiment of the present disclosure.

As shown. LPA can include the source collector module SO, the illumination system IL, and the projection system PS. The source collector module SO is constructed and arranged such that a vacuum environment can be maintained in an enclosing structure ES of the source collector module SO. An EUV radiation emitting hot plasma HP may be formed by a discharge produced plasma source. EUV radiation may be produced by a gas or vapor, for example Xe gas. Li vapor or Sn vapor in which the hot plasma HP is created to emit radiation in the EUV range of the electromagnetic spectrum. The hot plasma HP is created by, for example, an electrical discharge causing at least partially ionized plasma. Partial pressures of, for example, 10 Pa of Xe. Li. Sn vapor or any other suitable gas or vapor may be required for efficient generation of the radiation. In an embodiment, a plasma of excited tin (Sn) is provided to produce EUV radiation.

The radiation emitted by the hot plasma HP is passed from a source chamber SC into a collector chamber CC via an optional gas barrier or contaminant trap CT (in some cases also referred to as contaminant barrier or foil trap) which is positioned in or behind an opening in source chamber SC. The contaminant trap CT may include a channel structure. Contamination trap CT may also include a gas barrier or a combination of a gas barrier and a channel structure. The contaminant trap or contaminant barrier CT further indicated herein at least includes a channel structure, as known in the art.

The collector chamber CC may include a radiation collector CO which may be a so-called grazing incidence collector. Radiation collector CO has an upstream radiation collector side US and a downstream radiation collector side DS. Radiation that traverses radiation collector CO can be reflected off a grating spectral filter SF to be focused in a virtual source point IF along the optical axis indicated by the dot-dashed line ‘O’. The virtual source point IF can be referred to as the intermediate focus, and the source collector module can be arranged such that the intermediate focus IF is located at or near an opening OP in the enclosing structure ES. The virtual source point IF is an image of the radiation emitting plasma HP.

Subsequently the radiation traverses the illumination system IL, which may include a facetted field mirror device FM and a facetted pupil mirror device PM arranged to provide a desired angular distribution of the radiation beam B, at the mask device MA, as well as a desired uniformity of radiation amplitude at the mask device MA. Upon reflection of the beam of radiation B at the mask device MA, held by the support structure MT, a patterned beam PB is formed and the patterned beam PB is imaged by the projection system PS via reflective elements RE onto a substrate W held by the substrate table WT.

More elements than shown may generally be present in illumination optics unit IL and projection system PS. The grating spectral filter SF may optionally be present, depending upon the type of lithographic apparatus. Further, there may be more mirrors present than those shown in the figures, for example there may be 1-6 additional reflective elements present in the projection system PS.

Collector optic CO can be a nested collector with grazing incidence reflectors GR, just as an example of a collector (or collector mirror). The grazing incidence reflectors GR are disposed axially symmetric around the optical axis O and a collector optic CO of this type may be used in combination with a discharge produced plasma source, often called a DPP source.

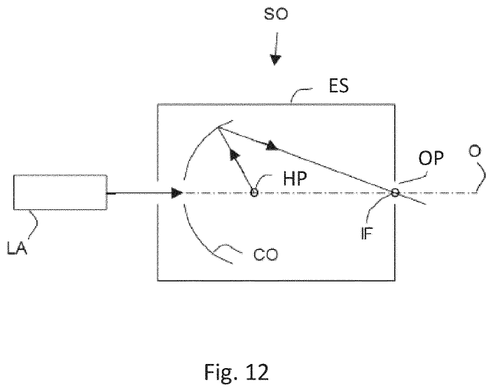

FIG. 12 is a detailed view of source collector module SO of lithographic projection apparatus LPA, according to an embodiment of the present disclosure.

Source collector module SO may be part of an LPA radiation system. A laser LA can be arranged to deposit laser energy into a fuel, such as xenon (Xe), tin (Sn) or lithium (Li), creating the highly ionized plasma HP with electron temperatures of several 10's of eV. The energetic radiation generated during de-excitation and recombination of these ions is emitted from the plasma, collected by a near normal incidence collector optic CO and focused onto the opening OP in the enclosing structure ES.

The concepts disclosed herein may simulate or mathematically model any generic imaging system for imaging sub wavelength features and may be especially useful with emerging imaging technologies capable of producing increasingly shorter wavelengths. Emerging technologies already in use include EUV (extreme ultraviolet), DUV lithography that is capable of producing a 193 nm wavelength with the use of an ArF laser, and even a 157 nm wavelength with the use of a Fluorine laser. Moreover. EUV lithography is capable of producing wavelengths within a range of 20-50 nm by using a synchrotron or by hitting a material (cither solid or a plasma) with high energy electrons in order to produce photons within this range.

Embodiments of the present disclosure can be further described by the following clauses.
1. A method for reducing wafer patterning errors caused by a mask device, the method comprising:
   obtaining a first mask design having a first portion associated with an optimized pupil, wherein the optimized pupil results from a source-mask optimization process;
   accessing information of an error on the mask device, wherein the error is located by using an inspection apparatus, wherein the mask device is fabricated with the first mask design; and
   performing source optimization by utilizing the first portion and the second portion in combination to generate a reoptimized pupil.
2. The method of clause 1, further comprising locating the error utilizing an inspection tool.
3. The method of clause 2, further comprising performing mask inspection of the mask device with the inspection tool.
4. The method of clause 2, further comprising performing wafer inspection of a wafer with the inspection tool.
5. The method of clause 1, further comprising obtaining a predicted result for the error.
6. The method of clause 5, wherein the second portion is identified based on the predicted result.
7. The method of clause 5, further comprising determining that the predicted result for the error is above a local threshold.
8. The method of clause 7, further comprising performing a lithographic manufacturing check (LMC) utilizing the mask device to obtain the predicted result for the second portion having the error.
9. The method of clause 8, further comprising determining with the LMC that the error is a process window limiter.
10. The method of clause 1, wherein the predicted result is a mask error enhancement factor (MEEF) obtained by performing an LMC utilizing the mask device.
11. The method of clause 1, wherein the predicted result is a depth of focus (DOF) and the error reduces the DOF.
12. The method of clause 1, wherein the first portion does not have the error or has a reduced error compared to the error in the second portion.
13. The method of clause 7, further comprising identifying portions of the mask device having errors of a type of error, wherein the source optimization is performed utilizing a portion where the error is the largest for the type of error.
14. The method of clause 13, wherein the type of error is a bias.
15. The method of clause 14, wherein the type of error is an X bias.
16. The method of clause 14, wherein the type of error is a Y bias.
17. The method of clause 14, wherein the type of error is an X and Y bias.
18. The method of clause 13, wherein the type of error is an edge shift.
19. The method of clause 18, wherein the type of error is an X edge shift.
20. The method of clause 18, wherein the type of error is a Y edge shift.
21. The method of clause 18, wherein the type of error is an X and Y edge shift.
22. The method of clause 13, wherein the type of error is an edge defect.
23. The method of clause 19, wherein the type of error is an X edge defect.
24. The method of clause 19, wherein the type of error is a Y edge defect.
25. The method of clause 19, wherein the type of error is an X and Y edge defect.
26. The method of clause 7, further comprising identifying portions of the mask device having different types of errors, wherein the source optimization is performed utilizing the portions that have the largest errors for the types of errors.
27. The method of clause 1, further comprising applying weights to the first portion and the second portion, the weights selected to establish a relative contribution of the first portion and the second portion in generating the reoptimized pupil.
28. The method of clause 27, further comprising:
   obtaining a plurality of predicted results for the mask device;
   locating a plurality of first errors on the mask device based on the plurality of predicted results; and
   identifying a plurality of second portions of the mask device with the located plurality of errors, wherein the weights are assigned to the plurality of second portions that have a largest error of a type of error, wherein the plurality of second portions includes the second portion.
29. The method of clause 27, further comprising iteratively adjusting the weights during successive source optimizations to improve a process window.
30. The method of clause 29, wherein the mask device and the reoptimized pupil result in the process window improved from the mask device and the optimized pupil.
31. The method of clause 1, wherein the source optimization is performed for a lithography system utilizing a numerical aperture (NA) greater than or equal to 0.4.
32. The method of clause 31, wherein the NA is 0.55.
33. The method of clause 31, further comprising stitching a mask device layout for use with the lithography system having the NA where the mask device is projected with a magnification that maintains a mask reflectance above 0.5.
34. The method of clause 1, wherein the mask design corresponds to one of a DRAM layer, a Storage Node (SP) layer, a Storage Node Pad (SNP) layer, or array patterns.
35. The method of clause 1, further comprising performing a vote-taking process utilizing the reoptimized pupil to generate a second reoptimized pupil.
36. The method of clause 1, wherein generating the reoptimized pupil does not include performing a vote-taking process.
37. The method of clause 1, the source optimization comprising generating a discrete pupil.
38. The method of clause 1, the source optimization comprising generating a free-form pupil.
39. The method of clause 1, the source optimization comprising generating a discrete pupil and a free-form pupil.
40. A non-transitory computer readable medium having instructions recorded thereon for reducing wafer patterning errors caused by a mask device, the instructions when executed by a computer having at least one programmable processor cause operations as in any of clauses 1-39.
41. A system for reducing wafer patterning errors caused by a mask device, the system comprising: at least one programmable processor; and
   a non-transitory computer readable medium having instructions recorded thereon, the instructions when executed by a computer having the at least one programmable processor cause operations as in any of clauses 1-39.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The combinations and sub-combinations of the elements disclosed herein constitute separate embodiments and are provided as examples only. Also, the descriptions above are intended to be illustrative, not limiting. Thus, it will be apparent to one skilled in the art that modifications may be made as described without departing from the scope of the claims set out below.

1. A non-transitory computer readable medium having instructions recorded thereon or therein, the instructions, when executed by at least one programmable processor, are configured to cause the at least one programmable processor to at least:
obtain a first mask design having a first portion associated with an optimized pupil, wherein the optimized pupil results from a source-mask optimization process;
access an error on a mask device for patterning illumination in lithography, wherein the error is located by using an inspection apparatus, wherein the mask device is fabricated with the first mask design;
identify a second portion of the mask device with the error; and
perform source optimization by utilizing the first portion and the second portion in combination to generate a reoptimized pupil.

2. The medium of claim 1, wherein the error is located utilizing a mask inspection apparatus or a wafer inspection apparatus.

3. The medium of claim 1, wherein the instructions are further configured to cause the at least one programmable processor to obtain a predicted result for the error, wherein the second portion is identified based on the predicted result.

4. The medium of claim 3, wherein the instructions are further configured to cause the at least one programmable processor to perform a lithographic manufacturing check (LMC) to obtain the predicted result for the second portion having the error.

5. The medium of claim 4, wherein the instructions are further configured to cause the at least one programmable processor to determine with the LMC that the error is a process window limiter.

6. The medium of claim 3, wherein the predicted result comprises a mask error enhancement factor (MEEF) obtained by performing an LMC utilizing the mask device, and/or a depth of focus (DOF) and the error reduces the DOF.

7. The medium of claim 1, wherein the first portion does not have the error or has a reduced error compared to the error in the second portion.

8. The medium of claim 1, wherein the instructions are further configured to cause the at least one programmable processor to identify portions of the mask device having errors of a type of error, wherein the source optimization is performed utilizing a portion where the error is the largest for the type of error.

9. The medium of claim 8, wherein the type of error is an X or Y bias, or an edge shift.

10. The medium of claim 1, wherein the instructions are further configured to cause the at least one programmable processor to apply weights to the first portion and the second portion, the weights selected to establish a relative contribution of the first portion and the second portion in generation of the reoptimized pupil.

11. The medium of claim 1, wherein the instructions are further configured to cause the at least one programmable processor to:
obtain a plurality of predicted results for the mask device;
locate a plurality of first errors on the mask device based on the plurality of predicted results; and
identify a plurality of second portions of the mask device with the located plurality of errors, wherein weights are assigned to the plurality of second portions that have a largest error of a type of error, wherein the plurality of second portions includes the second portion.

12. The medium of claim 10, wherein the instructions are further configured to cause the at least one programmable processor to iteratively adjust the weights during successive source optimizations to improve a process window.

13. The method of claim 1, wherein the instructions are further configured to cause the at least one programmable processor to perform a vote-taking process utilizing the reoptimized pupil to generate a second reoptimized pupil.

14. The medium of claim 1, wherein generation of the reoptimized pupil does not include performing a vote-taking process.

15. The medium of claim 1, wherein the source optimization comprises generation of a discrete pupil, or a free-form pupil.

16. A method for reducing wafer patterning errors caused by a mask device, the method comprising:
obtaining a first mask design having a first portion associated with an optimized pupil, wherein the optimized pupil results from a source-mask optimization process;
accessing information of an error on the mask device, wherein the error is located by using an inspection apparatus, wherein the mask device is fabricated with the first mask design; and
performing, by a hardware computer system, source optimization by utilizing the first portion and the second portion in combination to generate a reoptimized pupil.

17. The method of claim 16, further comprising obtaining a predicted result for the error, wherein the second portion is identified based on the predicted result.

18. The method of claim 17, further comprising performing a lithographic manufacturing check (LMC) utilizing the mask device to obtain the predicted result for the second portion having the error.

19. The method of claim 16, wherein the first portion does not have the error or has a reduced error compared to the error in the second portion.

20. The method of claim 16, further comprising identifying portions of the mask device having errors of a type of error, wherein the source optimization is performed utilizing a portion where the error is the largest for the type of error.
